(19) United States
(12) Patent Application Publication
(10) Pub. No.: US 2026/0013350 A1
(43) Pub. Date: Jan. 8, 2026

(54) ELECTRONIC DEVICE

(71) Applicant: Samsung Display Co., Ltd., Yongin-si (KR)

(72) Inventors: DO YEON HWANG, Yongin-si (KR); HYUN-CHOL BANG, Yongin-si (KR); KWANG-MIN KIM, Yongin-si (KR); Inhyeok YEO, Yongin-si (KR); DONG-YOON LEE, Yongin-si (KR)

(21) Appl. No.: 19/175,773

(22) Filed: Apr. 10, 2025

(30) Foreign Application Priority Data
Jul. 4, 2024 (KR) 10-2024-0088374

(51) Int. Cl. H10K 59/131

(52) U.S. Cl. CPC H10K 59/131

(57) ABSTRACT

An electronic device includes: a plurality of pixels; a first bus line and a second bus line extending in a first direction; a plurality of voltage lines extending in a second direction crossing the first direction, and connecting the plurality of pixels to the first bus line and the second bus line; a plurality of data lines extending in the second direction, and connected to the plurality of pixels; a first auxiliary line overlapping with the first bus line and the plurality of data lines in a plan view; and a second auxiliary line overlapping with the second bus line and the plurality of data lines in a plan view. A first width of the first auxiliary line in the first direction is different from a second width of the second auxiliary line in the first direction.

### CROSS-REFERENCE TO RELATED APPLICATION

The present application claims priority to and the benefit of Korean Patent Application No. 10-2024-0088374, filed on Jul. 4, 2024, in the Korean Intellectual Property Office, the entire disclosure of which is incorporated by reference herein.

### BACKGROUND

Aspects of embodiments of the present disclosure relate to an electronic device.

An electronic device has a variety of usages. In addition, because the electronic device may have a thin thickness and a light weight, the usage range of the electronic device has been extensively increased. Electronic devices may display an image to provide visual information for a user. For example, a display panel is provided in a vehicle, which may be one of the electronic devices. Recently, electronic devices may have various suitable shapes.

The above information disclosed in this Background section is for enhancement of understanding of the background of the present disclosure, and therefore, it may contain information that does not constitute prior art.

### SUMMARY

Embodiments of the present disclosure may be directed to an electronic device capable of preventing or substantially preventing a display quality from being degraded, even if an active region of a display panel has a polygonal shape.

According to one or more embodiments of the present disclosure, an electronic device includes: a plurality of pixels; a first bus line and a second bus line extending in a first direction; a plurality of voltage lines extending in a second direction crossing the first direction, and connecting the plurality of pixels to the first bus line and the second bus line; a plurality of data lines extending in the second direction, and connected to the plurality of pixels; a first auxiliary line overlapping with the first bus line and the plurality of data lines in a plan view; and a second auxiliary line overlapping with the second bus line and the plurality of data lines in a plan view. A first width of the first auxiliary line in the first direction is different from a second width of the second auxiliary line in the first direction.

In an embodiment, a first length of the first auxiliary line in the second direction at a first position may be equal to a second length of the first auxiliary line in the second direction at a second position different from the first position.

In an embodiment, a first length of the second auxiliary line in the second direction at a first position may be different from a second length of the second auxiliary line in the second direction at a second position different from the first position.

In an embodiment, a first length of the second auxiliary line in the second direction may decrease from a first position toward a second position.

In an embodiment, the plurality of pixels may be located in an active region, and the first bus line and the second bus line may be located in a non-active region.

In an embodiment, each of the plurality of data lines may include: a first portion in a non-overlap state with the first auxiliary line and the second auxiliary line; and a second portion overlapping with at least one of the first auxiliary line or the second auxiliary line in a plan view.

In an embodiment, a width of the second portion of each of the plurality of data lines in the second direction may be greater than a width of the first portion of the each of the plurality of data lines in the second direction.

In an embodiment, the first auxiliary line may be electrically connected to the first bus line, and the second auxiliary line may be electrically connected to the second bus line.

In an embodiment, the first auxiliary line and a data line from among the plurality of data lines may form a first auxiliary capacitor therebetween, and the data line and the first bus line may form a second auxiliary capacitor therebetween.

In an embodiment, the electronic device may further include a driving circuit configured to apply a data signal to the plurality of data lines, and apply a first voltage and a second voltage to the first bus line and the second bus line.

In an embodiment, the electronic device may further include voltage lines connected between the pixels and the first and second bus lines.

According to one or more embodiments of the present disclosure, an electronic device includes: a base layer; a transistor on the base layer, and including a gate electrode; a first signal line on the base layer; a second signal line in a layer different from that of the first signal line; a first auxiliary line in a layer the same as that of the gate electrode of the transistor; a second auxiliary line in a layer the same as that of the gate electrode of the transistor, and spaced from the first auxiliary line; a plurality of data lines in a layer the same as that of the first signal line; and a first bus line and a second bus line in a layer the same as that of the second signal line, each of the first bus line and the second bus line extending in a first direction. The first auxiliary line overlaps with the first bus line and the plurality of data lines in a plan view, and the second auxiliary line overlaps with the second bus line and the plurality of data lines in a plan view. A first width of the first auxiliary line in the first direction is different from a second width of the second auxiliary line in the first direction.

In an embodiment, the base layer may include an active region and a non-active region. The transistor, the first signal line, and the second signal line may be located in the active region. The first auxiliary line, the second auxiliary line, the plurality of data lines, the first bus line, and the second bus line may be located in the non-active region.

In an embodiment, a first length of the first auxiliary line in a second direction crossing the first direction at a first position may be equal to a second length of the first auxiliary line in the second direction at a second position different from the first position.

In an embodiment, a first length of the second auxiliary line in a second direction crossing the first direction at a first position may be different from a second length of the second auxiliary line in the second direction at a second position different from the first position.

In an embodiment, a length of the second auxiliary line in a second direction crossing the first direction may decrease from a first position toward a second position in the first direction.

In an embodiment, each of the plurality of data lines may include: a first portion in a non-overlap state with the first auxiliary line and the second auxiliary line; and a second portion overlapping with at least one of the first auxiliary line or the second auxiliary line in a plan view. A width of the second portion may be greater than a width of the first portion in a second direction crossing the first direction.

In an embodiment, the electronic device may further include: a first insulating layer between the first auxiliary line and the plurality of data lines; and a second insulating layer between the plurality of data lines and the first and second bus lines. The first bus line may be connected to the first auxiliary line through a contact hole penetrating the first insulating layer and the second insulating layer.

In an embodiment, the first auxiliary line and a data line from among the plurality of data lines may form a first auxiliary capacitor therebetween, and the data line and the first bus line may form a second auxiliary capacitor therebetween.

In an embodiment, the electronic device may further include a driving circuit configured to apply a data signal to the plurality of data lines, and apply a first voltage and a second voltage to the first bus line and the second bus line.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a view illustrating an interior of a vehicle.

FIG. 2 is a view of an electronic device according to an embodiment of the present disclosure.

FIG. 3 is a circuit diagram of a pixel according to an embodiment of the present disclosure.

FIG. 4 is a cross-sectional view of an electronic device according to an embodiment of the present disclosure.

FIG. 5 is a plan view of an electronic device according to an embodiment of the present disclosure.

FIG. 6 is a plan view of first, second, and third auxiliary lines illustrated in FIG. 5.

FIG. 7 is an enlarged plan view of a first region illustrated in FIG. 5.

FIG. 8 is a cross-sectional view corresponding to the line I-l′ of FIG. 7.

FIG. 9 is a cross-sectional view of an electronic device according to an embodiment of the present disclosure.

FIG. 10 is a cross-sectional view of an electronic device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense.

For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

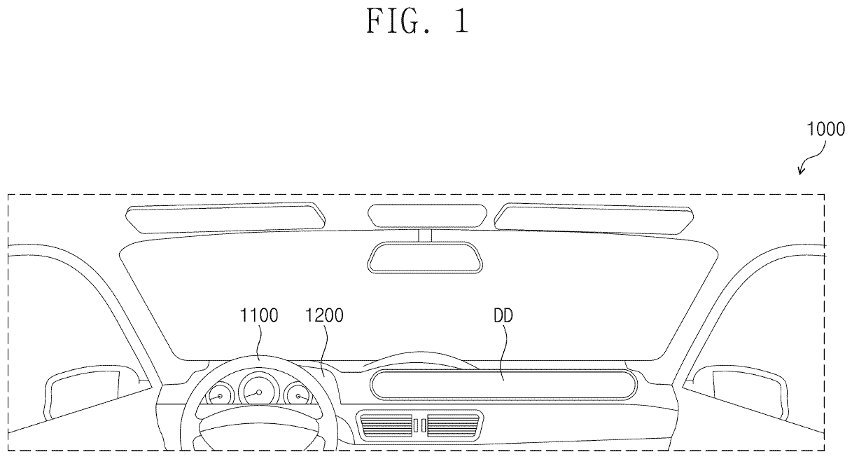

FIG. 1 is a view illustrating an interior of a vehicle 1000.

Referring to FIG. 1, the vehicle 1000, which may be a kind of an electronic device, may travel on a road or a railroad. The vehicle 1000 may include a three-wheeled vehicle, a four-wheeled vehicle, a construction machine, a motorcycle, a bicycle, or a train traveling on a railroad.

The vehicle 1000 includes an electronic device (e.g., a display device) DD, a steering wheel 1100, and a cluster 1200.

The electronic device DD may be disposed at a position corresponding to a dashboard of the vehicle 1000 to display an image. The steering wheel 1100 may be a circular steering device to change a direction (e.g., a forward direction) of the vehicle 1000 by moving the wheel of the vehicle 1000 to the left or right. The cluster 1200 may be an instrument panel to display the operating state of the vehicle 1000.

Although FIG. 1 illustrates the electronic device DD and the cluster 1200 implemented in the form of display devices that are independent from each other, the present disclosure is not limited thereto. According to an embodiment, the electronic device DD and the cluster 1200 may be implemented in the form of one display device (e.g., of the same display device) DD.

In addition, although the vehicle 1000 is shown and described in more detail below as one example of the electronic device according to an embodiment of the present disclosure, the present disclosure is not limited thereto. Some embodiments of the present disclosure described herein may be applied to various suitable electronic devices equipped with the electronic device (e.g., the display device) DD.

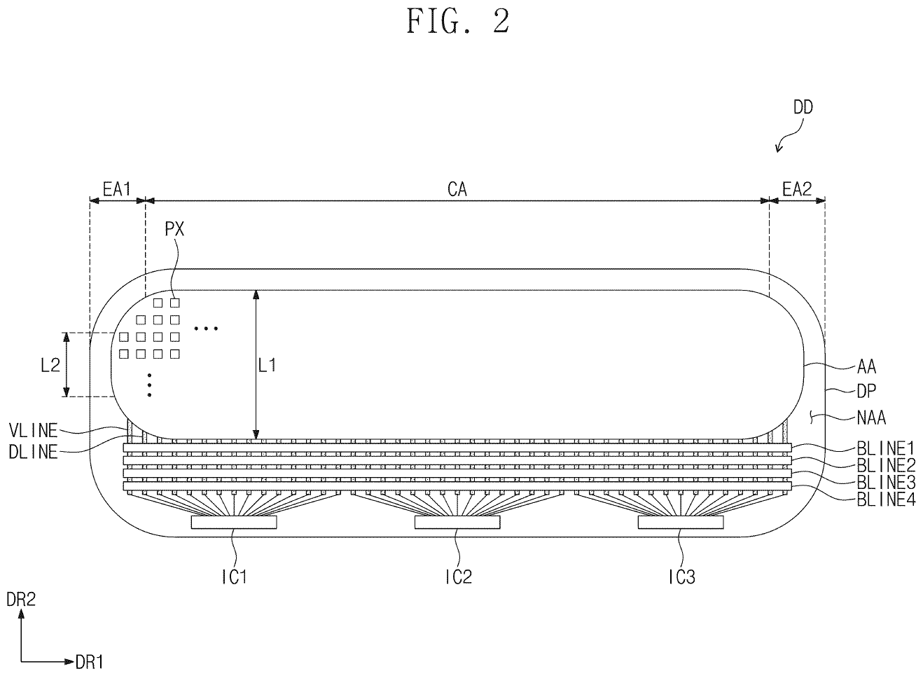

FIG. 2 is a view of the electronic device DD according to an embodiment of the present disclosure.

Referring to FIG. 2, the electronic device DD includes a display panel DP, and driving circuits IC1, IC2, and IC3.

The display panel DP includes pixels PX, voltage lines VLINE, data lines DLINE, and first to fourth bus lines BLINE1, BLINE2, BLINE3, and BLINE4.

The display panel DP may be divided into an active region AA and a non-active region NAA.

According to an embodiment, the driving circuits IC1, IC2, and IC3 may be disposed in the non-active region NAA of the display panel DP. The driving circuits IC1, IC2, and IC3 may be electrically connected to the pixels PX of the display panel DP through the voltage lines VLINE, the data line DLINE, and the first to fourth bus lines BLINE1, BLINE2, BLINE3, and BLINE4. The driving circuits IC1, IC2, and IC3 may apply data signals to the data lines DLINE. The driving circuits IC1, IC2, and IC3 may apply voltages to the voltage lines VLINE through the first to fourth bus lines BLINE1, BLINE2, BLINE3, and BLINE4.

According to an embodiment, each of the driving circuits IC1, IC2, and IC3 may be implemented in the form of an integrated circuit. According to an embodiment, the driving circuits IC1, IC2, and IC3 may be directly mounted on the display panel DP. According to an embodiment, the driving circuits IC1, IC2, and IC3 may be mounted on a flexible circuit film, and may be electrically connected to the pixels PX of the display panel DP through the flexible circuit film. In addition, the number of driving circuits IC1, IC2, and IC3 connected to the display panel DP may be variously modified as needed or desired.

The pixels PX are disposed in the active region AA, and the bus lines BLINE1, BLINE2, BLINE3, and BLINE4 are disposed in the non-active region NAA.

Although the voltage lines VLINE and the data lines DLINE are disposed in (e.g., only in) the non-active region NAA as illustrated in FIG. 2, the present disclosure is not limited thereto. The voltage lines VLINE and the data lines DLINE may extend in a second direction DR2 from the driving circuits IC1, IC2, and IC3 to the active region AA of the display panel DP.

According to an embodiment, the number of the voltage lines VLINE and the number the data lines DLINE may be determined depending on the number of the pixels PX. For example, the number of the pixels PX arranged along a first direction DR1 may be equal to the number of the data lines DLINE. The number of the voltage lines VLINE may be larger than the number of the pixels PX arranged along the first direction DR1.

According to an embodiment, the bus lines BLINE1, BLINE2, BLINE3, and BLINE4 may transmit mutually different signals from each other. According to an embodiment, the bus lines BLINE1, BLINE2, BLINE3, and BLINE4 may transmit mutually different voltages from each other. The voltage lines VLINE may be electrically connected to at least one of the bus lines BLINE1, BLINE2, BLINE3, or BLINE4.

The display panel DP may have a length in the first direction DR1 that is longer than a length in the second direction DR2.

The display panel DP has the active region AA having a length in the first direction DR1 that is longer than a length in the second direction DR2. The active region AA of the display panel DP may be divided into a first edge region EA1, a central region CA, and a second edge region EA2. The first edge region EA1, the central region CA, and the second edge region EA2 may be sequentially arranged along the first direction DR1.

Voltages (e.g., specific or predetermined voltages) applied from the driving circuits IC1, IC2, and IC3 may be supplied to the pixels PX through the voltage lines VLINE. In this case, a voltage applied to a pixel that is farther away from a voltage output terminal of each of the driving circuits IC1, IC2, and IC3 may be dropped. The bus lines BLINE1, BLINE2, BLINE3, and BLINE4 may have areas that are wider than those of the voltage lines VLINE. In addition, the length of each of the bus lines BLINE1, BLINE2, BLINE3, and BLINE4 may be longer than or equal to the length of the active region AA in the first direction DR1. Accordingly, the voltages may be supplied in uniform or substantially uniform voltage levels to the pixels PX through the bus lines BLINE1, BLINE2, BLINE3, and BLINE4.

Among the data lines DLINE disposed in the active region AA, the data lines DLINE disposed in the first edge region EA1 and the second edge region EA2 having the length L2 in the second direction DR2 may be shorter than the data lines DLINE disposed in the central region CA. The first edge region EA1 may have a shape that is narrowed in a direction opposite to the first direction DR1 from the central region CA. For example, an outer portion of the first edge region EA1 may have an oval shape, a semi-circular shape, or a rectangular shape having a rounded corner. Accordingly, the data lines DLINE disposed in the first edge region EA1 may have mutually different lengths from each other. The second edge region EA2 may have a shape that is narrowed in the first direction DR1 from the central region CA. For example, an outer portion of the second edge region EA2 may have an oval shape, a semi-circular shape, or a rectangular shape having a rounded corner. Accordingly, the data lines DLINE disposed in the second edge region EA2 may have mutually different lengths from each other.

In more detail, the length L1 of the data lines DLINE disposed in the central region CA may have a great difference from the length L2 of the data lines DLINE disposed at the outer most portion of each of the first edge region EA1 and the second edge region EA2. When the data lines DLINE have mutually different lengths from each other, a brightness difference resulting from a load difference between the data lines DLINE may be viewed by a user.

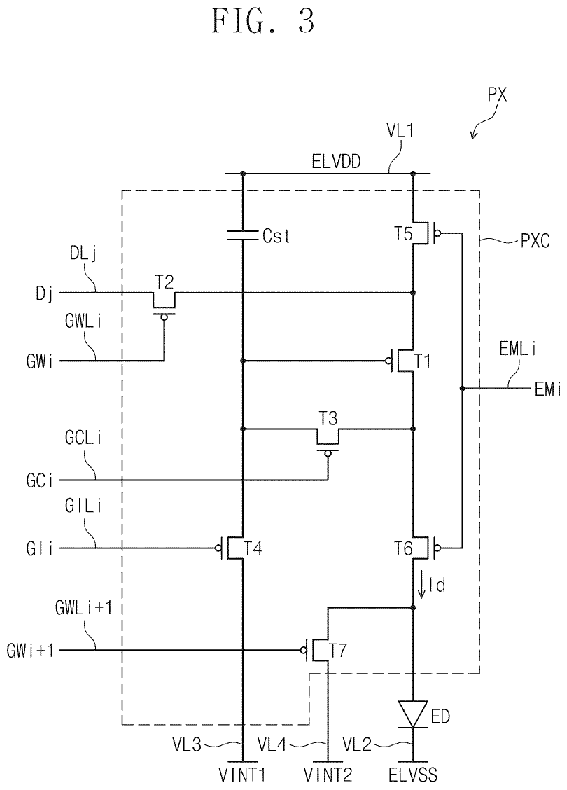

FIG. 3 is a circuit diagram of the pixel PX according to an embodiment of the present disclosure.

FIG. 3 illustrates the circuit diagram of the pixel PX connected to a j-th data line DLj among the data lines DLINE illustrated in FIG. 2, i-th scan lines GILi, GCLi, and GWLi among a plurality of scan lines, an (i+1)-th scan line GWLi+1 among the plurality of scan lines, and an i-th light emitting line EMLi among a plurality of light emitting lines, where i and j are natural numbers greater than or equal to 1.

According to an embodiment, the plurality of scan lines and the plurality of light emitting lines may extend from the driving circuits IC1, IC2, and IC3 illustrated in FIG. 2.

According to an embodiment, the plurality of scan lines and the plurality of light emitting lines may be signal lines extending from separate circuits (e.g., a scan driving circuit and a light emitting driving circuit) disposed in the display panel DP.

Each of the plurality of pixels PX illustrated in FIG. 2 may have a circuit configuration that is the same or substantially the same as that of the pixel PX illustrated in FIG. 3.

Referring to FIG. 3, the pixel PX of the electronic device according to an embodiment includes a pixel circuit PXC and at least one light emitting element ED. According to an embodiment, the light emitting element ED may be a light emitting diode. Hereinafter, one pixel PX may be described as including one light emitting element ED according to an embodiment by way of an example, but the present disclosure is not limited thereto. The pixel circuit PXC may include first to seventh transistors T1, T2, T3, T4, T5, T6, and T7, and a capacitor Cst.

According to an embodiment, each of the first to seventh transistors T1 to T7 may be a P-type transistor having a low-temperature polycrystalline silicon (LTPS) semiconductor layer. However, the present disclosure is not limited thereto, and each of the first to seventh transistors T1 to T7 may be N-type transistors including a semiconductor layer including an oxide semiconductor.

According to another embodiment, at least one of the first to seventh transistors T1 to T7 may be an N-type transistor, and the other remaining transistors may be P-type transistors. However, the present disclosure is not limited to the pixel PX illustrated in FIG. 3, and the circuit configuration of the pixel PX may be variously modified as needed or desired.

The scan lines GILi, GCLi, GWLi, and GWLi+1 may transmit scan signals Gli, GCi, GWi, and GWi+1. The light emitting line EMLi may transmit a light emitting signal EMi. The data line DLj may transmit a data signal Dj. The first to fourth driving voltage lines VL1, VL2, VL3, and VL4 may transmit a first driving voltage ELVDD, a second driving voltage ELVSS, a first initializing voltage VINT1, and a second initializing voltage VINT2, respectively.

According to an embodiment, the voltage lines VLINE illustrated in FIG. 2 may include first to fourth driving voltage lines VL1, VL2, VL3, and VL4. According to an embodiment, the first to fourth bus lines BLINE1, BLINE2, BLINE3, and BLINE4 may transmit the first driving voltage ELVDD, the second driving voltage ELVSS, the first initializing voltage VINT1, and the second initializing voltage VINT2, respectively. The first to fourth driving voltage lines VL1, VL2, VL3, and VL4 may be electrically connected to the first to fourth bus lines BLINE1, BLINE2, BLINE3, and BLINE4 illustrated in FIG. 2, respectively.

The first transistor T1 includes a first electrode connected to the first driving voltage line VL1 through the fifth transistor T5, a second electrode electrically connected to an anode of the light emitting element ED through the sixth transistor T6, and a gate electrode connected to a first terminal of the capacitor Cst. The first transistor T1 may receive a data signal Dj received through the data line DLj, in response to a switching operation of the second transistor T2, to supply a driving current Id to the light emitting element ED.

The second transistor T2 includes a first electrode connected to the data line DLj, a second electrode connected to the first electrode of the first transistor T1, and a gate electrode connected to the scan line GWLi. The second transistor T2 may be turned on in response to the scan signal GWi received through the scan line GWLi, and may transmit the data signal Dj received through the data line DLj to the first electrode of the first transistor T1.

The third transistor T3 includes a first electrode connected to the gate electrode of the first transistor T1, a second electrode connected to the second electrode of the first transistor T1, and a gate electrode connected with the scan line GCLi. The third transistor T3 may be turned on in response to the scan signal GCi received through the scan line GCLi, and may connect the gate electrode and the second electrode of the first transistor T1 to each other, such that the first transistor T1 is diode-connected.

The fourth transistor T4 includes a first electrode connected to the gate electrode of the first transistor T1, a second electrode connected to the third driving voltage line VL3 for transmitting the first initializing voltage VINT1, and a gate electrode connected to the scan line GILi. The fourth transistor T4 may be turned on in response to the scan signal Gli received through the scan line GILi, to perform an initialization operation for transmitting the first initializing voltage VINT1 to the gate electrode of the first transistor T1 to initialize a voltage of the gate electrode of the first transistor T1.

The fifth transistor T5 includes a first electrode connected to the first driving voltage line VL1, a second electrode connected to the first electrode of the first transistor T1, and a gate electrode connected to the light emitting line EMLi.

The sixth transistor T6 includes a first electrode connected to the second electrode of the first transistor T1, a second electrode connected to the anode of the light emitting element ED, and a gate electrode connected to the light emitting line EMLi.

The fifth transistor T5 and the sixth transistor T6 may be concurrently (e.g., simultaneously or substantially simultaneously) turned on with each other in response to the light emitting signal EMi received through the light emitting line EMLi. Accordingly, the first driving voltage ELVDD may be compensated for through the first transistor T1, which is diode-connected, and transmitted to the light emitting element ED.

The seventh transistor T7 includes a first electrode connected to the second electrode of the sixth transistor T6, a second electrode connected to the fourth driving voltage line VL4, and a gate electrode connected to the scan line GWLi+1. The seventh transistor T7 is turned on in response to the scan signal GWi+1 received through the scan line GWLi+1, to bypass a current of the anode of the light emitting element ED to the fourth driving voltage line VL4.

One terminal of the capacitor Cst is connected to the gate electrode of the first transistor T1, and another terminal of the capacitor Cst is connected to the first driving voltage line VL1. A cathode of the light emitting element ED may be connected to the second driving voltage line VL2 for transmitting the second driving voltage ELVSS. The pixel circuit PXC according to an embodiment is not limited to that illustrated in FIG. 3. The numbers of the transistors and the capacitors included in the pixel circuit PXC, and the connection relationship between the transistors and the capacitors, may be various modified as needed or desired.

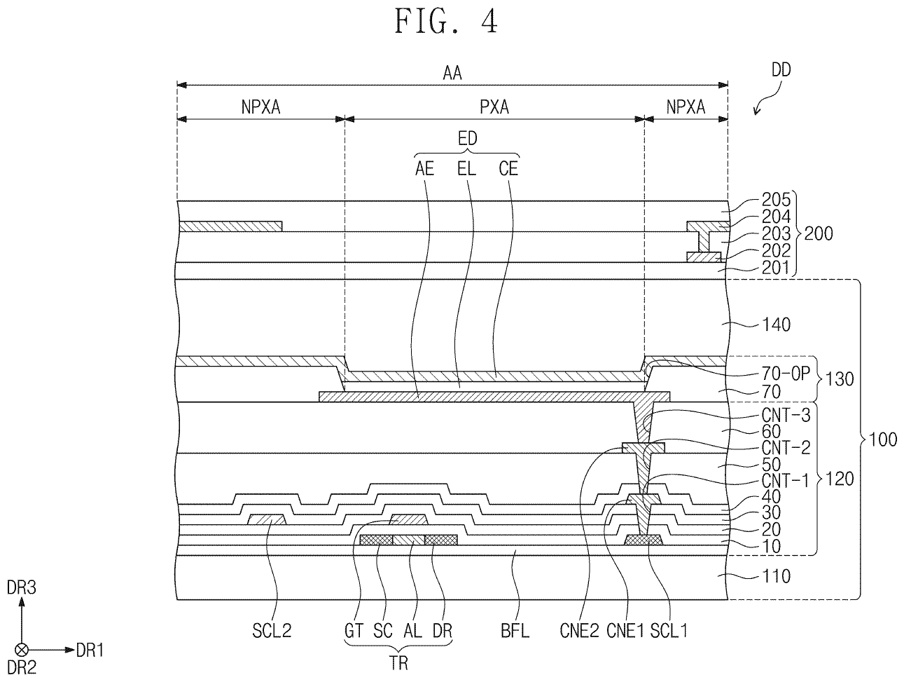

FIG. 4 is a cross-sectional view of the electronic device DD according to an embodiment of the present disclosure.

FIG. 4 illustrates a cross-sectional view of the active region AA of the electronic device DD.

Referring to FIG. 4, the display panel DP may include a display layer 100 and a sensor layer 200. The display layer 100 may include a base layer 110, a circuit layer 120, a light emitting element layer 130, and an encapsulating layer 140.

The base layer 110 may be a member that provides a base surface for disposing the circuit layer 120. The base layer 110 may be a glass substrate, a metal substrate, or a polymer substrate. However, the present disclosure is not limited thereto, and the base layer 110 may be an inorganic layer, an organic layer, or a composite material layer.

The base layer 110 may have a multi-layered structure. For example, the base layer 110 may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be referred to as a “base barrier layer”.

At least one inorganic layer may be formed on a top surface of the base layer 110. The inorganic layer may include at least one of an aluminum oxide, a titanium oxide, a silicon oxide, a silicon oxynitride, a zirconium oxide, or a hafnium oxide. The inorganic layer may have a multi-layered structure. Multiple inorganic layers may constitute a barrier layer and/or a buffer layer. According to an embodiment, the display layer 100 is illustrated as including a buffer layer BFL.

The buffer layer BFL may improve a bonding force between the base layer 110 and a semiconductor pattern. The buffer layer BFL may include a silicon oxide layer and a silicon nitride layer, and the silicon oxide layer and the silicon nitride layer may be alternately stacked.

The circuit layer 120 may be disposed on the base layer 110. The circuit layer 120 may include an insulating layer, a semiconductor pattern, a conductive pattern, and a signal line. The insulating layer, a semiconductor layer, and a conductive layer may be formed on the base layer 110 through a coating or deposition scheme. Thereafter, the insulating layer, the semiconductor layer, and the conductive layer may be selectively patterned through multiple photolithography processes. Afterwards, the semiconductor pattern, the conductive pattern, and the signal line included in the circuit layer 120 may be formed.

Semiconductor patterns SC, AL, DR, and SCL1 may be disposed on the buffer layer BFL. The semiconductor patterns SC, AL, DR, and SCL1 may include polysilicon. However, the present disclosure is not limited thereto, and the semiconductor patterns SC, AL, DR, and SCL1 may include amorphous silicon, a low-temperature polycrystalline silicon, or an oxide semiconductor.

FIG. 4 illustrates some of the semiconductor patterns SC, AL, DR, and SCL1, and other semiconductor patterns may be further disposed in other regions in another view. The semiconductor patterns SC, AL, DR, and SCL1 may be arranged in a suitable rule (e.g., a specific or predetermined rule) across the pixels PX. The semiconductor patterns SC, AL, DR, and SCL1 may have different electrical properties depending on doping states thereof. The semiconductor patterns SC, AL, DR, and SCL1 may include first regions SC, DR, and SCL having a higher conductivity, and a second region AL having a lower conductivity. The first regions SC, DR, and SCL1 may be doped with an N-type dopant or a P-type dopant. A P-type transistor may include a doping region doped with the P-type dopant, and an N-type transistor may include a doping region doped with the N-type dopant. The second region AL may be a non-doped region, or a region that is doped at a lower concentration than those of the first regions SC, DR, and SCL1.

The first regions SC, DR, and SCL1 may have a conductivity higher than the conductivity of the second region AL, and may serve as an electrode or a signal line.

The second region AL may correspond to an active region (e.g., a channel) of a transistor. In other words, a first portion (e.g., the second region AL) among the semiconductor patterns SC, AL, DR, and SCL1 may be the active region AL of the transistor TR, and a second portion (e.g., the first regions SC and DR) among the semiconductor patterns SC, AL, DR, and SCL1 may be a source region SC or a drain region DR of the transistor TR. A third portion (e.g., the first region SCL1) may be a connection electrode or a first connection signal line SCL.

Each of the pixels PX may have an equivalent circuit including a plurality of transistors, at least one capacitor, and at least one light emitting element. However, the equivalent circuit of the pixel may be variously modified as needed or desired. One transistor TR and one light emitting element ED included in the pixel PX (e.g., see FIG. 3) are illustrated in FIG. 4. The transistor TR illustrated in FIG. 4 may be any one of the first to seventh transistors T1 to T7 illustrated in FIG. 3.

The source region SC, the active region AL, and the drain region DR of the transistor TR may be formed from the semiconductor patterns SC, AL, DR, and SCL1. The source region SC and the drain region DR may extend in directions opposite to each other from the active region AL, when viewed in a cross-sectional view. FIG. 4 illustrates a portion of the first connection signal line SCL1 formed from the semiconductor pattern SC, AL, DR, and SCL1. In another view, the first connection signal line SCL1 may be connected to the drain region DR of the transistor TR (e.g., when viewed in a plan view).

A first insulating layer 10 may be disposed on the buffer layer BFL. The first insulating layer 10 may be commonly provided in a plurality of pixels to cover the semiconductor patterns SC, AL, DR, and SCL1. The first insulating layer 10 may be an inorganic layer and/or an organic layer, and may have a single layer structure or a multi-layered structure. The first insulating layer 10 may include at least one of an aluminum oxide, a titanium oxide, a silicon oxide, a silicon nitride, a silicon oxynitride, a zirconium oxide, or a hafnium oxide. According to some embodiments of the present disclosure, the first insulating layer 10 may be a single layer of a silicon oxide layer. In addition to the first insulating layer 10, the insulating layer of the circuit layer 120, which is described in more detail below, may be an inorganic layer and/or an organic layer, and may have a single layer structure or a multi-layered structure. The inorganic layer may include at least one of the above-described inorganic materials, but the present disclosure is not limited thereto.

A gate electrode GT of the transistor TR is disposed on the first insulating layer 10. The gate electrode GT may be a portion of a metal pattern. The gate electrode GT is overlapped with (e.g., overlaps with) the active region AL. In the process for doping or reducing the semiconductor patterns SC, AL, DR, and SCL1, the gate electrode GT may serve as a mask.

A second insulating layer 20 may be disposed on the first insulating layer 10 to cover the gate electrode GT. The second insulating layer 20 may be commonly overlapped with the pixels. The second insulating layer 20 may be an inorganic layer and/or an organic layer, and may have a single layer structure or multi-layered structure. The second insulating layer 20 may include at least one of silicon oxide, silicon nitride, or silicon oxynitride. According to an embodiment, the second insulating layer 20 may have a multi-layered structure including a silicon oxide layer and a silicon nitride layer.

A second connection signal line SCL2 is disposed on the second insulating layer 20. The second connection signal line SCL2 may be referred to as a first signal line. According to an embodiment, the second connection signal line SCL2 may be connected to the gate electrode GT of the transistor TR, when viewed in a plan view.

According to an embodiment, the second connection signal line SCL2 may be connected to any one of the first to seventh transistors T1 to T7 of the pixel PX (e.g., see FIG. 3).

A third insulating layer 30 may be disposed on the second insulating layer 20. The third insulating layer 30 may have a single layer structure or a multi-layered structure. For example, the third insulating layer 30 may have a multi-layered structure including a silicon oxide layer and a silicon nitride layer.

A first connection electrode CNE1 may be disposed on the third insulating layer 30. The first connection electrode CNE1 may be connected to the connection signal line SCL1 through a contact hole CNT-1 formed through (e.g., penetrating) the first insulating layer 10, the second insulating layer 20, and the third insulating layer 30.

A fourth insulating layer 40 may be disposed on the third insulating layer 30. The fourth insulating layer 40 may be a single layer of a silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection signal line CNE2 may be referred to as a second signal line. The second connection electrode CNE2 may be connected to the first connection electrode CNE1 through a contact hole CNT-2 formed through (e.g., penetrating) the fourth insulating layer 40 and the fifth insulating layer 50.

A sixth insulating layer 60 may be disposed on the fifth insulating layer 50 to cover the second connection electrode CNE2. The sixth insulating layer 60 may be an organic layer.

The light emitting element layer 130 may be disposed on the circuit layer 120. The light emitting element layer 130 may include the light emitting element ED. For example, the light emitting element layer 130 may include an organic light emitting material, an inorganic light emitting material, an organic-inorganic light emitting material, a quantum dot, a quantum rod, a micro-LED, or a nano-LED. Hereinafter, the light emitting element ED may be described in more detail in the context of an organic light emitting element, but the present disclosure is not particularly limited thereto.

The light emitting element ED may include a first electrode AE, a light emitting layer EL, and a second electrode CE. The first electrode AE may be disposed on the sixth insulating layer 60. The first electrode AE may be connected with the second connection electrode CNE2 through a contact hole CNT-3 formed through (e.g., penetrating) the sixth insulating layer 60.

A pixel defining layer 70 may be disposed on the sixth insulating layer 60 to cover a portion of the first electrode AE. An opening 70-OP is defined in the pixel defining layer 70. The opening 70-OP of the pixel defining layer 70 exposes at least a portion of the first electrode AE.

A display region 1000A (e.g., see FIG. 1A) may include a light emitting region PXA, and a non-light emitting region NPXA adjacent to the light emitting region PXA. The non-light emitting region NPXA may surround (e.g., around a periphery of) the light emitting region PXA. According to an embodiment, the light emitting region PXA is defined to correspond to the portion of the first electrode AE exposed by the opening 70-OP.

The light emitting layer EL may be disposed on the first electrode AE. The light emitting layer EL may be disposed in a region defined by the opening 70-OP. FIG. 4A illustrates that the light emitting layer EL is disposed in the opening 70-OP, but the present disclosure is not limited thereto. For example, the light emitting layer EL may extend to cover a side surface of the pixel defining layer 70 and a portion of a top surface of the pixel defining layer 70, which define the opening 70-OP.

According to an embodiment of the present disclosure, the light emitting layer EL may be separately formed with respect to the pixels. When the light emitting layer EL is separately formed with respect to the pixels, each of light emitting layers EL may emit light of at least one of a blue color, a red color, or a green color. However, the present disclosure is not limited thereto, and the light emitting layer EL may be connected with the pixels to be commonly provided in the pixels. In this case, the light emitting layer EL may provide a blue light or a white light.

The second electrode CE may be disposed on the light emitting layer EL. The second electrode CE may have an integral form, and may be disposed in the plurality of pixels in common.

According to an embodiment of the present disclosure, a hole control layer may be disposed on the first electrode AE and the light emitting layer EL. The hole control layer may be disposed in the light emitting region PXA and the non-light emitting region NPXA in common. The hole control layer may include a hole transfer layer, and may further include a hole injection layer. An electron control layer may be interposed between the light emitting layer EL and the second electrode CE. The electron control layer may include an electron transfer layer, and may further include an electron injection layer. The hole control layer and the electron control layer may be formed in the plurality of pixels in common by using an open mask or an ink-jet process.

The encapsulating layer 140 may be disposed on the light emitting element layer 130. The encapsulating layer 140 may include an inorganic layer, an organic layer, and an inorganic layer sequentially stacked. However, the layers constituting the encapsulating layer 140 are not limited thereto. The inorganic layers may protect the light emitting element layer 130 from moisture and oxygen, and the organic layer may protect the light emitting element layer 130 from a foreign material, such as dust particles. The inorganic layers may include a silicon nitride layer, a silicon oxynitride layer, a silicon oxide layer, a titanium oxide layer, or an aluminum oxide layer. The organic layer may include an acrylic-based organic layer, but the present disclosure is not limited thereto.

The sensor layer 200 may be formed on the display layer 100 through a successive process. In this case, the sensor layer 200 may be expressed as being directly disposed on the display layer 100. The phrase “˜being directly disposed˜” may indicate that a third component is not intervened between the sensor layer 200 and the display layer 100. In other words, an additionally adhesive member may not be interposed between the sensor layer 200 and the display layer 100. As another example, the sensor layer 200 may be bonded to the display layer 100 through an adhesive member. The adhesive member may include a suitable adhesive agent or a sticking agent.

The sensor layer 200 may include a base layer 201, a first conductive layer 202, an intermediate insulating layer 203, a second conductive layer 204, and a cover insulating layer 205.

The base layer 201 may be an inorganic layer including at least one of silicon nitride, silicon oxynitride, or silicon oxide. As another example, the base layer 201 may be an organic layer including an epoxy resin, an acrylate resin, or an imide-based resin. The base layer 201 may have a single layer structure, or a multi-layered structure including layers that are stacked in the third direction DR3.

Each of the first conductive layer 202 and the second conductive layer 204 may have a single layer structure, or a multi-layered structure including layers that are stacked in the third direction DR3.

Each of the first conductive layer 202 and the second conductive layer 204 having the single layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer, such as poly(3,4-ethylenedioxythiophene) (PEDOT), metal nanowires, or graphene.

Each of the first conductive layer 202 and the second conductive layer 204 having the multi-layered structure may include a plurality of metal layers. The metal layers may have, for example, a three-layered structure of titanium/aluminum/titanium. The conductive layer having the multi-layered structure may include at least one metal layer and at least one transparent conductive layer.

According to an embodiment of the present disclosure, the thickness of the first conductive layer 202 may be greater than or equal to the thickness of the second conductive layer 204. When the thickness of the first conductive layer 202 is greater than the thickness of the second conductive layer 204, a resistance of the components (e.g., an electrode, a sensing pattern, or a bridge pattern) included in the first conductive layer 202 may be reduced. In addition, because the first conductive layer 202 may be disposed below (e.g., underneath) the second conductive layer 204, even if the thickness of the first conductive layer 202 is increased, a probability in which the components included in the first conductive layer 202 may be viewed by an external light reflection may be lower than that of the second conductive layer 204.

At least one of the intermediate insulating layer 203 or the cover insulating layer 205 may include an inorganic layer. The inorganic layer may include at least one of an aluminum oxide, a titanium oxide, a silicon oxide, a silicon nitride, a silicon oxynitride, a zirconium oxide, or a hafnium oxide.

At least one of the intermediate insulating layer 203 or the cover insulating layer 205 may include an organic layer. The organic layer may include at least one of an acrylic resin, a methacryl resin, polyisoprene, a vinyl resin, an epoxy resin, a urethane resin, a cellulose resin, a siloxane resin, a polyimide resin, a polyamide resin, or a perylene resin.

While a total of two conductive layers of the first conductive layer 202 and the second conductive layer 204 have been described with reference to FIG. 4 above, the present disclosure is not limited thereto. For example, the sensor layer 200 may include at least three conductive layers.

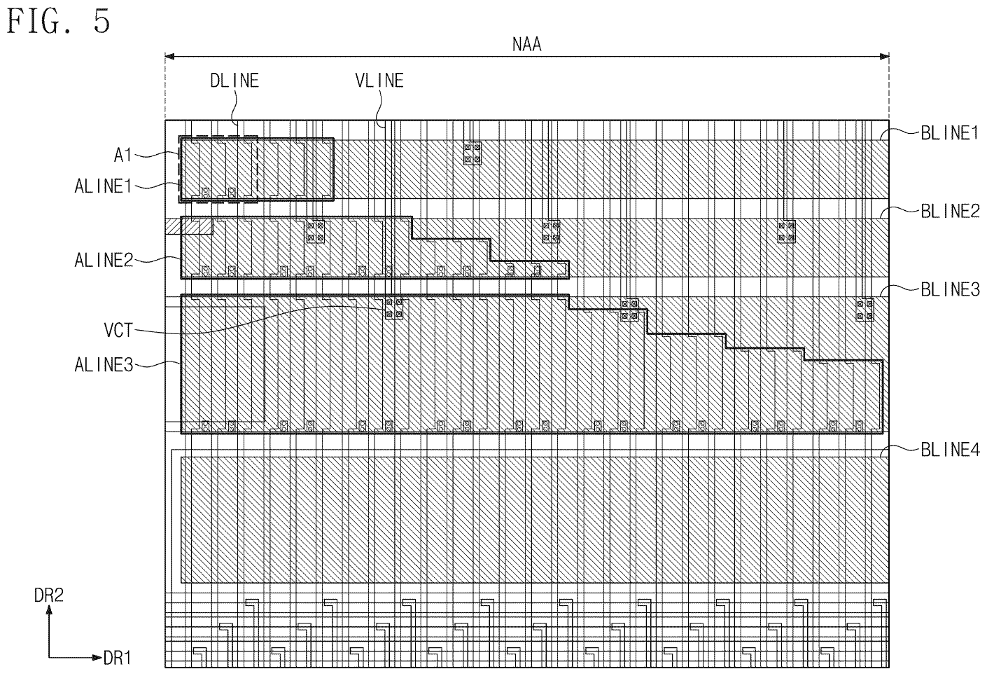

FIG. 5 is a plan view of the electronic device DD according to an embodiment of the present disclosure.

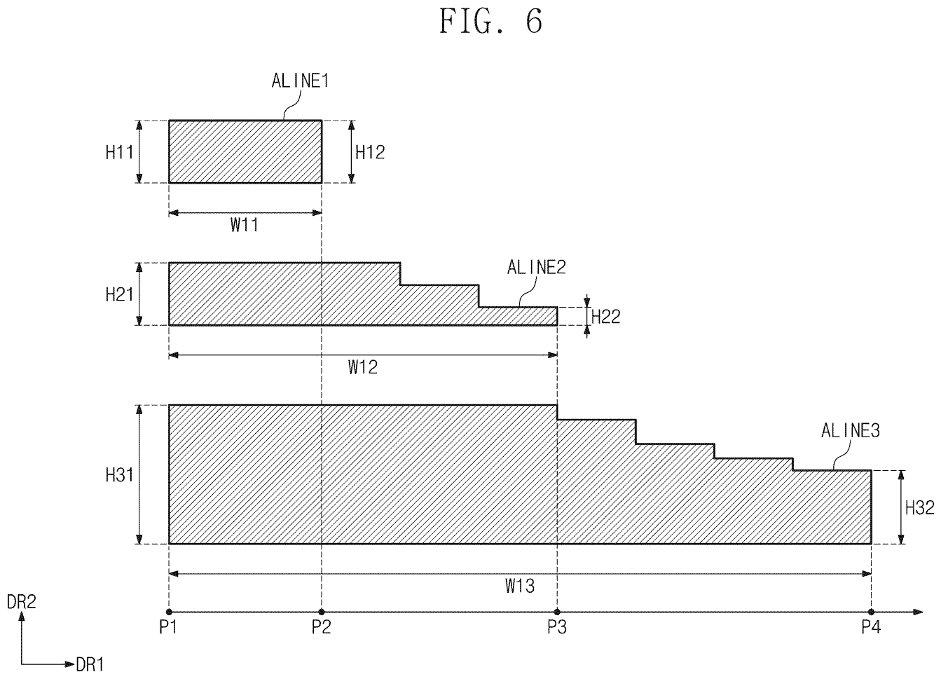

FIG. 6 is a plan view of first, second, and third auxiliary lines ALINE1, ALINE2, and ALINE3 illustrated in FIG. 5.

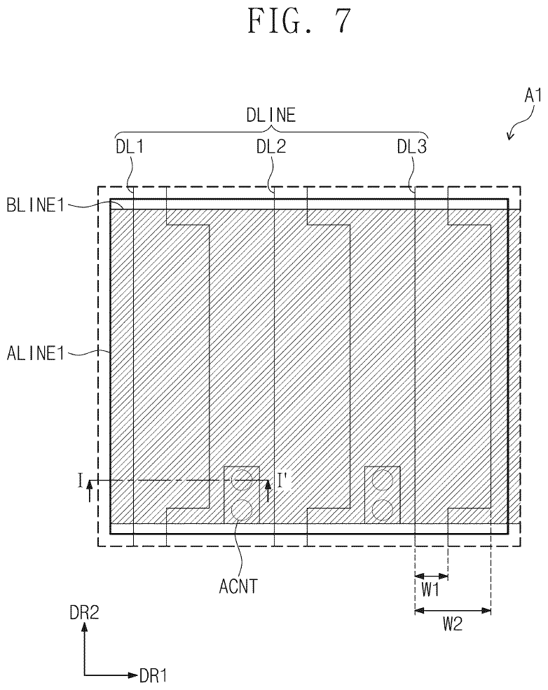

FIG. 7 is an enlarged plan view of a first region A1 illustrated in FIG. 5.

FIG. 5 illustrates in a plan view of a portion of the non-active region NAA of the electronic device DD, in which the first to fourth bus lines BLINE1, BLINE2, BLINE3, and BLINE4 are disposed.

Referring to FIGS. 5, 6, and 7, the first to fourth bus lines BLINE1, BLINE2, BLINE3, and BLINE4 may be disposed to extend in the first direction DR1, and may be spaced apart from each other in the second direction DR2. According to an embodiment, the first to fourth bus lines BLINE1, BLINE2, BLINE3, and BLINE4 may transmit voltages having mutually different voltage levels from each other.

According to an embodiment, the first to fourth bus lines BLINE1, BLINE2, BLINE3, and BLINE4 may be disposed in the same layer as each other, while being spaced apart from each other.

While FIG. 5 illustrates that the first to fourth bus lines BLINE1, BLINE2, BLINE3, and BLINE4 are sequentially disposed in a direction opposite to the second direction DR2, the present disclosure is not limited thereto. The sequence in which the first to fourth bus lines BLINE1, BLINE2, BLINE3, and BLINE4 are disposed may be variously modified as needed or desired.

According to an embodiment, the first bus line BLINE1 and the second bus line BLINE2 may be equal to each other in a width (or a length) in the second direction DR2. The width of the third bus line BLIN3 in the second direction DR2 may be greater than the width of the first bus line BLINE1 in the second direction DR2. The width of the fourth bus line BLIN4 in the second direction DR2 may be greater than the width of the third bus line BLINE3 in the second direction DR2. The width of each of the bus lines BLINE1, BLINE2, BLINE3, and BLINE4 in the second direction DR2 may be variously modified as needed or desired.

The data lines DLINE and the voltage lines VLINE are disposed to extend in the second direction DR2 and to be spaced apart from each other in the first direction DR1. In other words, the data lines DLINE and the voltage lines VLINE are disposed while crossing the first to fourth bus lines BLINE1, BLINE2, BLINE3, and BLINE4.

The data lines DLINE and the voltage lines VLINE may be disposed in the same layer as each other, or in mutually different layers from each other.

In other words, the data lines DLINE and the voltage lines VLINE may be disposed in a layer different from the layers for the first to fourth bus lines BLINE1, BLINE2, BLINE3, and BLINE4. According to an embodiment, the first to fourth bus lines BLINE1, BLINE2, BLINE3, and BLINE4 may be disposed on the data lines DLINE and the voltage lines VLINE. The voltage lines VLINE may be electrically connected to any one of the bus lines BLINE1, BLINE2, BLINE3, and BLINE4 through a voltage contact VCT.

The first to third auxiliary lines ALINE1, ALINE2, and ALINE3 may be disposed to extend in the first direction DR1, while being spaced apart from each other in the second direction DR2. According to an embodiment, the first to third auxiliary lines ALINE1, ALINE2, and ALINE3 may be disposed in the same layer as each other, while being spaced apart from each other.

While FIG. 5 illustrates the first to third auxiliary lines ALINE1, ALINE2, and ALINE3 are sequentially disposed in a direction opposite to the second direction DR2, the present disclosure is not limited thereto. The sequence in which the first to third auxiliary lines ALINE1, ALINE2, and ALINE3 are disposed may be variously modified as needed or desired.

As illustrated in FIG. 6, the first auxiliary line ALINE1 may have a first width W11 in the first direction DR1. The second auxiliary line ALINE2 may have a second width W12 in the first direction DR1. The third auxiliary line ALINE3 may have a third width W13 in the first direction DR1.

The first auxiliary line ALINE1 may have an eleventh length H11 in the second direction DR2 at a first position P1, and a twelfth length H12 in the second direction DR2 at a second position P2. According to an embodiment, the eleventh length H11 and the twelfth length H12 may be equal to or substantially equal to each other, but the present disclosure is not limited thereto. According to an embodiment, the eleventh length H11 and the twelfth length H12 may be different from each other. According to an embodiment, the length of the second auxiliary line ALINE2

in the second direction DR2 may be gradually reduced in the first direction DR1. In other words, the second auxiliary line ALINE2 may have a 21^{st} length H21 in the second direction DR2 at the first position P1, and a 22^{nd} length H22 in the second direction DR2 at the third position P3. According to an embodiment, the 22^{nd} length H22 may be shorter than the 21^{st} length H21, but the present disclosure is not limited thereto. According to an embodiment, the 21^{st} length H21 may be greater than or equal to the 22^{nd} length.

The length of the third auxiliary line ALINE3 in the second direction DR2 may be gradually reduced in the first direction DR1. In other words, the third auxiliary line ALINE3 may have a 31^{st} length H31 in the second direction DR2 at the first position P1, and a 32^{nd} length H32 in the second direction DR2 at a fourth position P4. According to an embodiment, the 32^{nd} length H32 may be shorter than the 31^{st} length H31, but the present disclosure is not limited thereto. According to an embodiment, the 31^{st} length H31 may be greater than or equal to the 32^{nd} length.

The first position P1, the second position P2, the third position P3, and the fourth position P4 may be positions on a line that is parallel to or substantially parallel to a virtual line extending in the first direction DR1.

As illustrated in FIG. 7, the data lines DLINE may include data lines DL1, DL2, and DL3. The data lines DL1, DL2, and DL3 may be disposed to extend in the second direction DR2, while being spaced apart from each other in the first direction DR1.

According to an embodiment, the first auxiliary line ALINE1, the second auxiliary line ALINE2, and the third auxiliary line ALINE3 may be overlapped with (e.g., may overlap with) the first bus line BLINE1, the second bus line BLINE2, and the third bus line BLNE3, when viewed in a plan view. In addition, according to an embodiment, the first auxiliary line ALINE1, the second auxiliary line ALINE2, and the third auxiliary line ALINE3 may be overlapped with (e.g., may overlap with) the data lines D1, D2, and DL3, respectively, when viewed in a plan view.

Because the first auxiliary line ALINE1 may be overlapped with (e.g., may overlap with) each of the data lines D1, D2, and DL3, an auxiliary capacitor may be formed.

Each of the data lines D1, D2, and DL3 includes a first portion, which is in a non-overlap state with the first bus line BLINE1 and the first auxiliary line ALINE1, and a second portion overlapped with (e.g., overlapping with) the first bus line BLINE1 and the first auxiliary line ALINE1. The first portion of each of the data lines D1, D2, and DL3 may have the first width W1 in the first direction DR1. The second portion of each of the data lines D1, D2, and DL3 may have the second width W2 that is greater than the first width W1. Because the second width W2 of the second portion of the each of the data lines DL1, DL2, and DL3 is greater than the first width W1, an overlap area with the first auxiliary line ALINE1 may be widened. Accordingly, a capacitance of the auxiliary capacitor formed between the data lines DL1, DL2, and DL3 and the first auxiliary line ALINE1 may be increased.

The first bus line BLINE1 may be electrically connected to the first auxiliary line ALINE1 through an auxiliary contact ACNT. The auxiliary contact ACNT may be disposed to be spaced apart from each of the data lines DL1, DL2, and DL3.

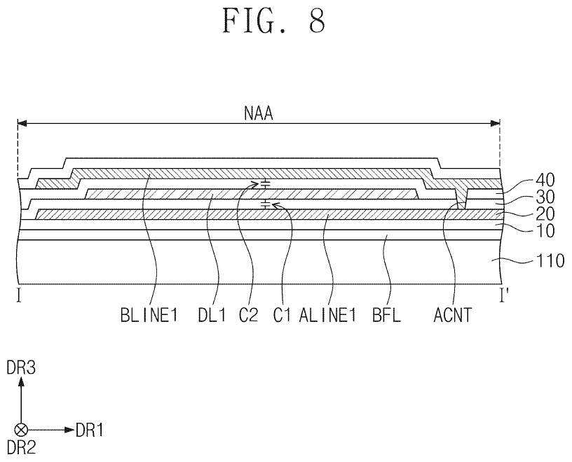

FIG. 8 is a cross-sectional view taken along the line I-l′ of FIG. 7.

Referring to FIGS. 4, 7, and 8, the first auxiliary line ALINE1, the data line DL1, and the first bus line BLINE1 may be formed in the same layers as the layers for the gate electrode GT of the transistor TR, the second connection signal line SCL2, and the first connection electrode CNE1 illustrated in FIG. 4, and may include the same materials as those of the gate electrode GT of the transistor TR, the second connection signal line SCL2, and the first connection electrode CNE1.

According to an embodiment, the first auxiliary line ALINE1, the data line DL1, and the first bus line BLINE1 may include metal layers. The metal layer may include molybdenum, silver, titanium, copper, aluminum, or a suitable alloy thereof.

The first bus BLINE1 may be connected to the first auxiliary line ALINE1 through the auxiliary contact ACNT formed through (e.g., penetrating) the second insulating layer 20 and the third insulating layer 30.

The first auxiliary line ALINE1 and the data line DL1 may form a first auxiliary capacitor C1. The data line DL1 and the first bus line BLINE1 may form a second auxiliary capacitor C2.

Because the first bus line BLINE1 and the first auxiliary line ALINE1 may be electrically connected to each other through the auxiliary contact ACNT, the first auxiliary capacitor C1 and the second auxiliary capacitor C2 may be connected to each other in parallel. As the first auxiliary line ALINE1 is added, the capacitance between the first bus line BLINE1 and the data line DL1 may be equal to ‘C1+C2’, which is the sum of the capacitance of the first auxiliary capacitor C1 and the capacitance of the second auxiliary capacitor C2.

Referring back to FIGS. 5 and 6, because the length of each of the second auxiliary line ALINE2 and the third auxiliary line ALINE3 in the second direction DR2 may be narrowed in the first direction DR1, the capacitance formed between the second auxiliary line ALINE2 and the third auxiliary line ALINE3 may be gradually reduced in the first direction DR1. In other words, the capacitance formed by the second auxiliary line ALINE2 and the third auxiliary line ALINE3 may be increased in the direction opposite to the first direction DR1.

Because the length of the data lines DLINE may be reduced in the direction opposite to the first direction DR1, a load difference may be compensated for by the capacitance formed by the first auxiliary line ALINE1, the second auxiliary line ALINE2, and the third auxiliary line ALINE3.

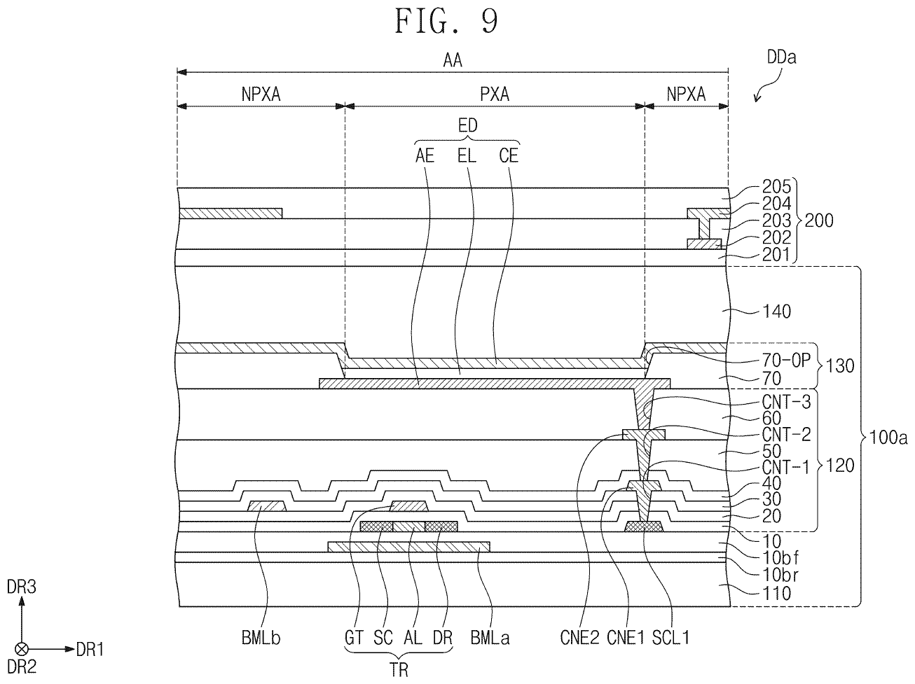

FIG. 9 is a cross-sectional view of an electronic device DDa according to an embodiment of the present disclosure.

FIG. 9 illustrates a cross-sectional view of the active region AA of the electronic device DDa.

Referring to FIG. 9, the electronic device DDa may include a display layer 100a and the sensor layer 200. The display layer 100a may include the base layer 110, a barrier layer 10br, a first shielding electrode BMLa, a buffer layer 10bf, the circuit layer 120, the light emitting element layer 130, and the encapsulating layer 140.

In FIG. 9, the same reference numerals are assigned to the same or substantially the same (or similar) components as those of the electronic device DD described above with reference to FIG. 4, and thus, redundant description thereof may not be repeated.

The barrier layer 10br may be disposed on the base layer 110. The barrier layer 10br may prevent or substantially prevent foreign substances from being introduced from the outside. The barrier layer 10br may include at least one inorganic layer. The barrier layer 10br may include a silicon oxide layer and a silicon nitride layer. The silicon oxide layer may include a plurality of silicon oxide layers, and the silicon nitride layer may include a plurality of silicon nitride layers. In this case, the silicon oxide layers and the silicon nitride layers may be alternately stacked.

The first shielding electrode BMLa may be disposed on the barrier layer 10br. The first shielding electrode BMLa may include a metal. The first shielding electrode BMLa may include molybdenum (Mo), which may have excellent heat resistance, an alloy containing molybdenum (Mo), titanium (Ti), or an alloy containing titanium (Ti). The first shielding electrode BMLa may receive a bias voltage. The first shielding electrode BMLa may receive the first driving voltage ELVDD. The first shielding electrode BMLa may block an electrical potential from affecting the transistor TR due to a polarization phenomenon. The first shielding electrode BMLa may block external light from reaching the transistor TR. According to an embodiment of the present disclosure, the first shielding electrode BMLa may be another electrode, or a floating electrode isolated from a wire.

The buffer layer 10bf may be disposed on the barrier layer 10br. The buffer layer 10bf may prevent or substantially prevent metal atoms or impurities from diffusing from the base layer 110 to the first semiconductor pattern SP1 disposed at an upper layer. The buffer layer 10bf may include at least one inorganic layer. The buffer layer 10bf may include a silicon oxide layer and a silicon nitride layer.

The semiconductor patterns SC, AL, DR, and SCL1 may be disposed on the barrier layer 10bf. The first insulating layer 10 may be disposed on the buffer layer 10bf. The gate electrode GE of the transistor TR may be disposed on the first insulating layer 10.

The second insulating layer 20 may be disposed on the first insulating layer 10 to cover the gate electrode GT. A second shielding electrode BMLb may be disposed on the second insulating layer 20. According to an embodiment of the present disclosure, the second shielding electrode BMLb may be omitted as needed or desired.

When at least one of the first to seventh transistors T1 to T7 illustrated in FIG. 3 is an N-type transistor including a semiconductor layer including an oxide semiconductor, the second shielding electrode BMLb may be disposed to correspond to a lower portion of the oxide transistor.

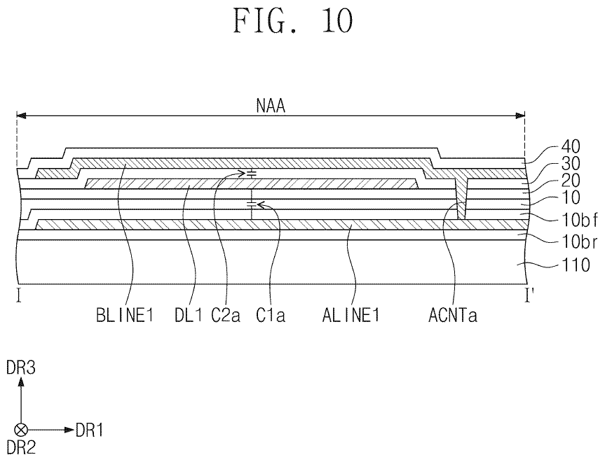

FIG. 10 is a cross-sectional view of the electronic device DDa according to an embodiment of the present disclosure.

The cross-sectional view illustrated in FIG. 10 may correspond to the line I-I′ of FIG. 7.

Referring to FIGS. 4, 7, 9, and 10, the first auxiliary line ALINE1, the data line DL1, and the first bus line BLINE1 may be formed in layers that are the same as the layers for the first shielding electrode BMLa, the second shielding electrode BMLb, and the first connection electrode CNE1 illustrated in FIG. 9, and may include a material that is the same as the materials of the first shielding electrode BMLa, the second shielding electrode BMLb, and the first connection electrode CNE1.

According to an embodiment, each of the first auxiliary line ALINE1, the data line DL1, and the first bus line BLINE1 may include metal layers. The metal layer may include molybdenum, silver, titanium, copper, aluminum, or an alloy thereof.

The first bus BLINE1 may be connected to the first auxiliary line ALINE1 through an auxiliary contact ACNTa formed through (e.g., penetrating) the second insulating layer 20 and the third insulating layer 30.

The first auxiliary line ALINE1 and the data line DL1 form a first auxiliary capacitor C1a. The data line DL1 and the first bus line BLINE1 form a second auxiliary capacitor C2a.

Because the first bus line BLINE1 and the first auxiliary line ALINE1 may be electrically connected to each other through the auxiliary contact ACNTa, the first auxiliary capacitor C1a and the second auxiliary capacitor C2a may be connected to each other in parallel. As the first auxiliary line ALINE1 is added, the capacitance between the first bus line BLINE1 and the data line DL1 may be equal to ‘C1a+C2a’, which is the sum of the capacitance of the first auxiliary capacitor C1a and the capacitance of the second auxiliary capacitor C2a.

In addition, as described above with reference to FIG. 7, when the area of the data line DL1, which may be overlapped with (e.g., may overlap with) the first bus line BLINE1 and the first auxiliary line ALINE1, is increased, the capacitance formed between the first bus line BLINE1 and the data line DL1 may be further increased.

The electronic device having the above configuration according to some embodiments of the present disclosure may include the display panel having a polygonal shape. Even if the data lines have different lengths from each other depending on the position of the display panel, a load difference may be compensated for by the auxiliary capacitor formed by an auxiliary line overlapped with (e.g., overlapping with) the data lines. Accordingly, a difference in a display quality depending on the position of the display panel may be minimized or reduced.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a plurality of pixels;
a first bus line and a second bus line extending in a first direction;
a plurality of voltage lines extending in a second direction crossing the first direction, and connecting the plurality of pixels to the first bus line and the second bus line;
a plurality of data lines extending in the second direction, and connected to the plurality of pixels;
a first auxiliary line overlapping with the first bus line and the plurality of data lines in a plan view; and
a second auxiliary line overlapping with the second bus line and the plurality of data lines in a plan view,
wherein a first width of the first auxiliary line in the first direction is different from a second width of the second auxiliary line in the first direction.

2. The electronic device of claim 1, wherein a first length of the first auxiliary line in the second direction at a first position is equal to a second length of the first auxiliary line in the second direction at a second position different from the first position.

3. The electronic device of claim 1, wherein a first length of the second auxiliary line in the second direction at a first position is different from a second length of the second auxiliary line in the second direction at a second position different from the first position.

4. The electronic device of claim 1, wherein a first length of the second auxiliary line in the second direction decreases from a first position toward a second position.

5. The electronic device of claim 1, wherein the plurality of pixels are located in an active region, and the first bus line and the second bus line are located in a non-active region.

6. The electronic device of claim 5, wherein each of the plurality of data lines comprises:
a first portion in a non-overlap state with the first auxiliary line and the second auxiliary line; and
a second portion overlapping with at least one of the first auxiliary line or the second auxiliary line in a plan view.

7. The electronic device of claim 6, wherein a width of the second portion of each of the plurality of data lines in the second direction is greater than a width of the first portion of the each of the plurality of data lines in the second direction.

8. The electronic device of claim 1, wherein the first auxiliary line is electrically connected to the first bus line, and the second auxiliary line is electrically connected to the second bus line.

9. The electronic device of claim 8, wherein the first auxiliary line and a data line from among the plurality of data lines form a first auxiliary capacitor therebetween, and
wherein the data line and the first bus line form a second auxiliary capacitor therebetween.

10. The electronic device of claim 1, further comprising a driving circuit configured to apply a data signal to the plurality of data lines, and apply a first voltage and a second voltage to the first bus line and the second bus line.

11. The electronic device of claim 1, further comprising voltage lines connected between the pixels and the first and second bus lines.

12. An electronic device comprising:
a base layer;
a transistor on the base layer, and comprising a gate electrode;
a first signal line on the base layer;
a second signal line in a layer different from that of the first signal line;
a first auxiliary line in a layer the same as that of the gate electrode of the transistor;
a second auxiliary line in a layer the same as that of the gate electrode of the transistor, and spaced from the first auxiliary line;
a plurality of data lines in a layer the same as that of the first signal line; and
a first bus line and a second bus line in a layer the same as that of the second signal line, each of the first bus line and the second bus line extending in a first direction,
wherein the first auxiliary line overlaps with the first bus line and the plurality of data lines in a plan view,
wherein the second auxiliary line overlaps with the second bus line and the plurality of data lines in a plan view, and
wherein a first width of the first auxiliary line in the first direction is different from a second width of the second auxiliary line in the first direction.

13. The electronic device of claim 12, wherein the base layer comprises an active region and a non-active region,
wherein the transistor, the first signal line, and the second signal line are located in the active region, and
wherein the first auxiliary line, the second auxiliary line, the plurality of data lines, the first bus line, and the second bus line are located in the non-active region.

14. The electronic device of claim 12, wherein a first length of the first auxiliary line in a second direction crossing the first direction at a first position is equal to a second length of the first auxiliary line in the second direction at a second position different from the first position.

15. The electronic device of claim 12, wherein a first length of the second auxiliary line in a second direction crossing the first direction at a first position is different from a second length of the second auxiliary line in the second direction at a second position different from the first position.

16. The electronic device of claim 12, wherein a length of the second auxiliary line in a second direction crossing the first direction decreases from a first position toward a second position in the first direction.

17. The electronic device of claim 12, wherein each of the plurality of data lines comprises:
a first portion in a non-overlap state with the first auxiliary line and the second auxiliary line; and
a second portion overlapping with at least one of the first auxiliary line or the second auxiliary line in a plan view, and
wherein a width of the second portion is greater than a width of the first portion in a second direction crossing the first direction.

18. The electronic device of claim 12, further comprising:
a first insulating layer between the first auxiliary line and the plurality of data lines; and
a second insulating layer between the plurality of data lines and the first and second bus lines,
wherein the first bus line is connected to the first auxiliary line through a contact hole penetrating the first insulating layer and the second insulating layer.

19. The electronic device of claim 18, wherein the first auxiliary line and a data line from among the plurality of data lines form a first auxiliary capacitor therebetween, and
wherein the data line and the first bus line form a second auxiliary capacitor therebetween.

20. The electronic device of claim 12, further comprising a driving circuit configured to apply a data signal to the plurality of data lines, and apply a first voltage and a second voltage to the first bus line and the second bus line.
